(19) United States
(12) Patent Application Publication
(10) Pub. No.: US 2009/0032844 A1
(43) Pub. Date: Feb. 5, 2009

(54) SEMICONDUCTOR DEVICE AND METHOD OF MANUFACTURING THE SAME

(75) Inventors: Jusuke OGURA, Kawasaki-shi (JP); Hikaru KOKURA, Kawasaki-shi (JP); Hiroshi MORIOKA, Kawasaki-shi (JP); Kazuo KAWAMURA, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: FUJITSU LIMITED, Kawasaki-shi (JP); FUJITSU MICROELECTRONICS LIMITED, Tokyo (JP)

(21) Appl. No.: 12/181,765

(22) Filed: Jul. 29, 2008

(30) Foreign Application Priority Data
Jul. 31, 2007 (JP) 2007-199144

(51) Int. Cl. H01L 29/778; H01L 21/336

(52) U.S. Cl. 257/190; 438/285; 257/E21.403; 257/E29.246

(57) ABSTRACT

A method of manufacturing a semiconductor device has forming a transistor including a source and a drain, forming a mixed crystal layer over the source and the drain, forming a silicide layer over the mixed crystal layer, forming a first insulating film and a second insulating film over the silicide layer, forming a contact hole, performing an oxygen plasma treatment, and forming a conductive plug in the contact hole.

### CROSS-REFERENCE TO RELATED APPLICATION

This application is based upon and claims the benefit of priority from the prior Japanese Patent Application No. 2007-199144 filed on Jul. 31, 2007, the entire contents of which are incorporated herein by reference.

### BACKGROUND

The present invention relates to a semiconductor device and a method of manufacturing the semiconductor device.

Miniaturization of semiconductor devices has been progressing to improve the degree of integration and operating speed of semiconductor integrated circuits. With the progress in miniaturization of a semiconductor device, the gate length of a metal oxide semiconductor (MOS) transistor has become shorter. A MOS transistor is a field-effect transistor having a gate insulating film and a gate electrode over a semiconductor active region.

Applying stress to a semiconductor crystal of a channel region of the MOS transistor improves the mobility of an electron or a hole.

The electron mobility in an n-channel MOS (nMOS) transistor can be improved by applying tensile stress to the channel region. The hole mobility in a p-channel MOS (pMOS) transistor can be improved by applying compressive stress to the channel region.

In the case where the gate of the MOS transistor is arranged to lie in a <110> direction on a (001) surface of a silicon crystal substrate, the ON current increases upon application of tensile stress in the gate length direction and increases upon application of tensile stress in the gate width direction if the MOS transistor is the nMOS transistor, and the ON current decreases upon application of tensile stress in the gate length direction and increases upon application of tensile stress in the gate width direction if the MOS transistor is the pMOS transistor. According to a known technology, an etching stopper film having tensile stress is formed over the nMOS transistor and an etching stopper film having compressive stress is formed over the pMOS transistor.

In the case of the nMOS transistor, application of tensile stress to the silicon crystal in the channel increases the electron mobility if the source/drain region is composed of a silicon-carbon (Si—C) mixed crystal having a smaller lattice constant than a silicon crystal of the silicon substrate. In contrast, in the case of the pMOS transistor, application on compressive stress to the silicon crystal in the channel increases the hole mobility if the source/drain region is composed of a silicon-germanium (Si—Ge) mixed crystal having a larger lattice constant than the silicon crystal of the silicon substrate.

Appropriate stresses can be applied to the pMOS transistor by etching the silicon substrate in the source/drain region of the pMOS transistor and growing the Si—Ge mixed crystal there over, and appropriate stresses can be applied to the nMOS transistor by etching the silicon substrate in the source/drain region of the nMOS transistor and growing the Si—C mixed crystal there over.

A method of manufacturing a complementary metal oxide semiconductor (CMOS) transistor is also investigated. According to this method, the silicon substrate in the source/drain region in of the pMOS transistor is etched, the Si—Ge mixed crystal is grown to apply compressive stress, a silicide layer is formed over the Si—Ge mixed crystal, and then a silicon nitride film having tensile stress is formed over the pMOS transistor and the nMOS transistor so as to apply tensile stress to the nMOS transistor.

However, in the CMOS semiconductor devices having a Si—Ge mixed crystal in the source/drain of the pMOS transistor and the silicon nitride film of tensile stress formed over the pMOS transistor, many contact failures have occurred.

### SUMMARY

One aspect of the invention is a method of manufacturing a semiconductor device which forms a transistor including a source and a drain, forms a mixed crystal layer over the source and the drain, forms a silicide layer over the mixed crystal layer, forms a first insulating film and a second insulating film over the silicide layer, forms a contact hole, performs an oxygen plasma treatment, and forms a conductive plug in the contact hole.

### BRIEF DESCRIPTION OF THE DRAWINGS

FIGS. 1A to 1M are cross-sectional views showing a method of manufacturing a semiconductor device according to an embodiment of the present invention;

FIGS. 2A to 2D are graphs showing the measurement results of gate contact resistances of pMOS and nMOS transistors;

FIG. 2E is a graph showing the measurement results of the gate contact resistance and source-drain contact resistance of a pMOS transistor;

FIGS. 3A to 3C are cross-sectional views showing a method of manufacturing a semiconductor device according to another embodiment; and

FIGS. 4A and 4B are cross-sectional views showing a method of manufacturing a semiconductor device according to another further embodiment.

### PREFERRED EMBODIMENTS

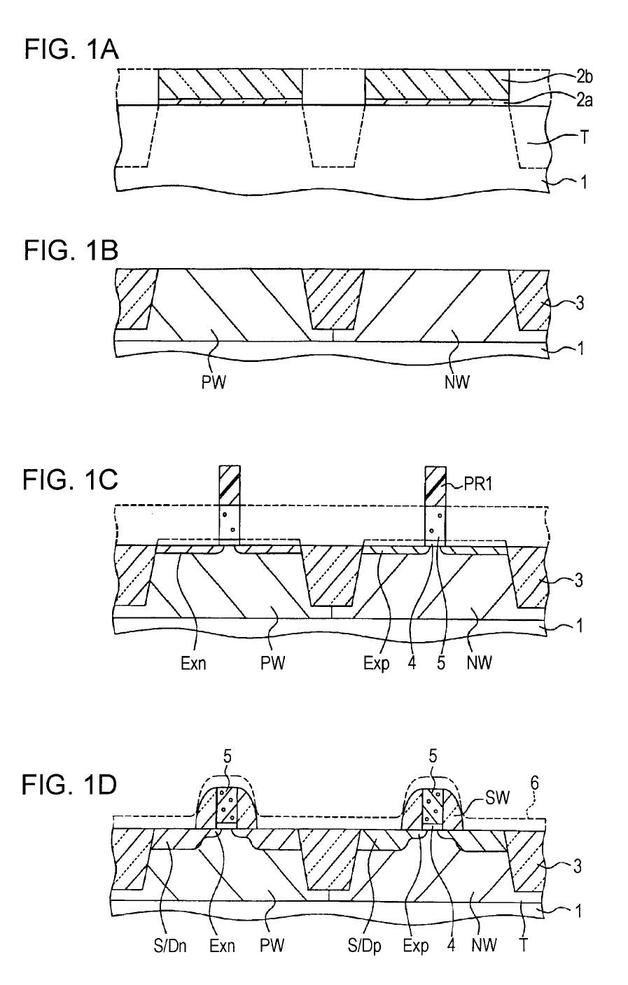

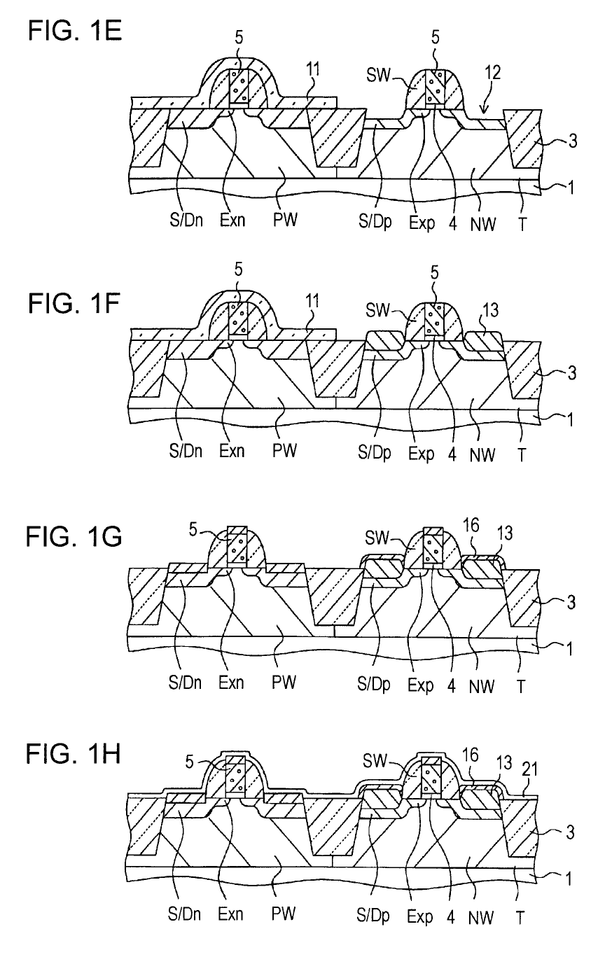

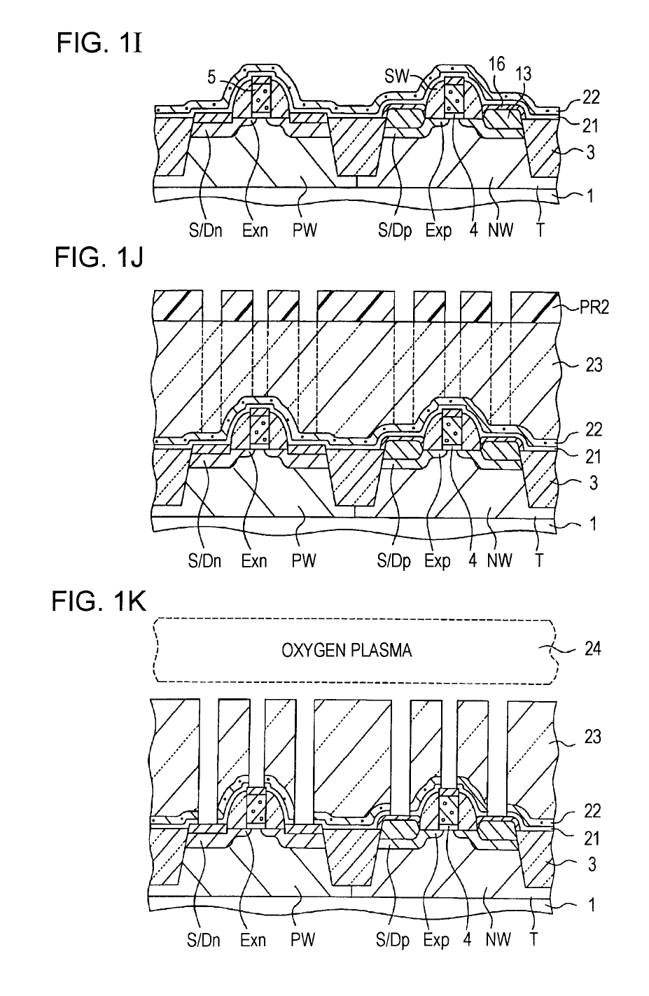

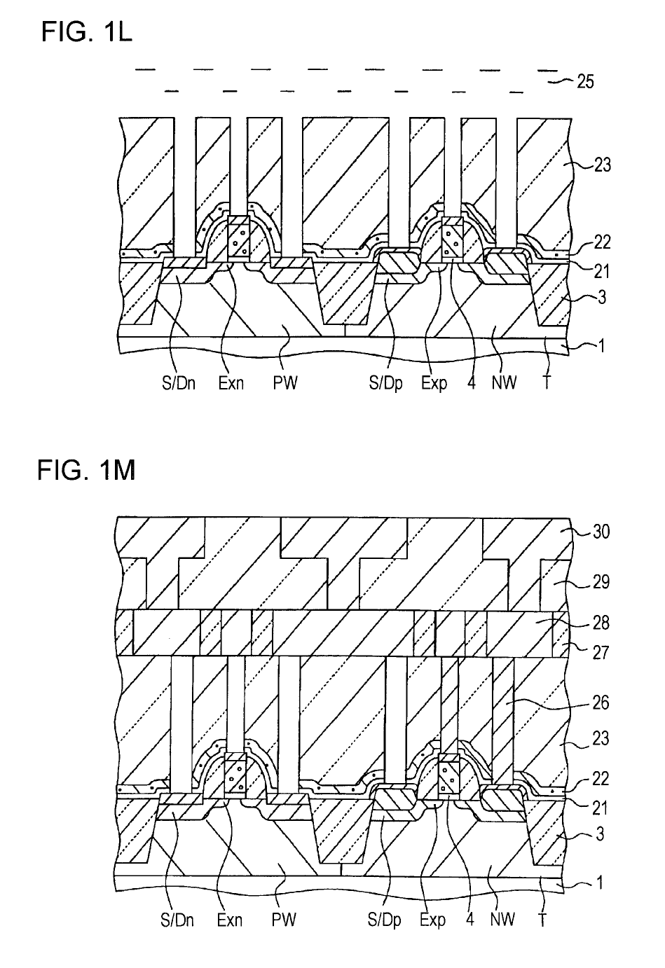

FIGS. 1A to 1M are cross-sectional views showing a method of manufacturing a semiconductor device according to an embodiment of the present invention.

Element isolation regions that define active regions are formed in a silicon substrate 1. The element isolation regions are formed by, for example, a shallow trench isolation (STI) method.

As shown in FIG. 1A, a silicon oxide film 2a and a silicon nitride film 2b having trenches over the element isolation regions are sequentially formed over a surface of the silicon substrate 1. The silicon substrate 1 exposed in the trenches is etched to form trenches T having a depth of, for example, 240 nm to 350 nm.

Referring to FIG. 1B, a silicon oxide film is formed by a high-density plasma chemical vapor deposition (HDP-CVD) method to fill the trenches with the silicon oxide film, and the silicon oxide film deposited over the substrate surface is polished away by chemical mechanical polishing (CMP). During the CMP process, the silicon nitride film 2b functions as a stopper. After the CMP process, the silicon oxide film 2a is removed with hot phosphoric acid, for example. The silicon nitride film 2b is removed with diluted hydrofluoric acid or the like so as to form element isolation regions 3. Then, ions of a p-type impurity are implanted to form a p-type well PW in an nMOS transistor region and ions of an n-type impurity are implanted to form an n-type well NW in a pMOS transistor region by using a resist mask as a mask.

Referring to FIG. 1C, the silicon oxide film over the active region surface is removed with diluted hydrofluoric acid or the like, and thermal oxidation is conducted again to form a gate insulating film 4 having a thickness of 1 nm to 15 nm, for example. In the case where gate insulating films of several different thicknesses are to be formed, etching steps and thermal oxidation steps are repeated such as forming the thickest gate insulating film first, removing part of the gate insulating film by etching, and then forming the next thickest gate insulating film. Nitrogen may be introduced into the silicon oxide film. Another insulating film having a dielectric constant higher than that of the silicon oxide film may be formed over the silicon oxide film. A polysilicon layer having a thickness of, for example, about 75 nm to 120 nm is formed over the gate insulating film 4. A photoresist pattern PR1 having the shape of a gate electrode is formed over the polysilicon layer, and the polysilicon layer thereunder is patterned by etching to form a gate electrode 5. The gate insulating film 4 may also be removed by this etching. Then, the photoresist pattern PR1 is removed by ashing or the like. A photoresist pattern covering the PMOS transistor region is then formed, and ions of an n-type impurity are implanted to form an n-type extension region Exn. For example, arsenic ions are implanted at an acceleration energy of 5 keV and a dose of 1E15 ions/cm². A photoresist pattern covering the nMOS transistor region is formed, and ions of a p-type impurity are implanted into the pMOS transistor region to form a p-type extension region Exp. For example, boron ions are implanted at an acceleration energy of 5 keV and a dose of 1E15 ions/cm² to form the p-type extension region Exp.

As shown in FIG. 1D, a side wall spacer SW which is an insulating film such as a silicon nitride film is formed over the side wall of the gate electrode 5. For example, a silicon nitride film 6 having a thickness of 15 nm to 75 nm is deposited over the substrate while covering the gate electrode 5 by thermal CVD at a temperature of 600° C. to 800° C. using dichlorosilane and ammonia as source gas. Alternatively, the silicon oxide film or a laminate of a silicon oxide film and a silicon nitride film may be used instead of the silicon nitride film. A silicon oxide film can be deposited by thermal CVD at a temperature of 550° C. to 700° C. using tetraethoxysilane and oxygen as source gas. The silicon nitride film 6 is subjected to reactive ion etching (RIE) using hydrofluorocarbon as etching gas so as to form the side wall spacer SW over the side wall of the gate electrode 5.

The nMOS transistor region is covered with a resist mask and ions of a p-type impurity, e.g., boron, are implanted deeper than the p-type extension region Exp at a high concentration so as to form a source/drain region S/Dp. The pMOS region is covered with the resist mask and ions of an n-type impurity, e.g., phosphorus, are implanted into the nMOS transistor region deeper than the n-type extension region Exn, and at a higher concentration than the Exn so as to form a source/drain region S/Dn.

As shown in FIG. 1E, a silicon oxide film 11 is deposited to a thickness of about 40 nm by, for example, the HDP-CVD method. A resist pattern covering the nMOS transistor region is formed and the silicon oxide film 11 in the pMOS transistor region is removed by etching. The silicon oxide film 11 functions as a mask during etching of the silicon substrate and epitaxial growth of a Si—Ge layer. The silicon oxide film 11 may be formed by a method other than the HDP-CVD method.

The silicon substrate 1 is etched in the pMOS transistor region while using the silicon oxide film 11 as a mask. For example, RIE is performed at a depth of about 35 nm using hydrogen bromide as etching gas. Then, the silicon surface is cleaned using hydrogen chloride. As a result, a recess 12 is formed.

Referring to FIG. 1F, an epitaxial layer 13 of Si—Ge or silicon-germanium-carbon (Si—Ge—C) is formed in the recess 12 in the pMOS transistor region. For example, the deposition temperature is set to 500° C. to 800° C., and SiH₂Cl₂ is fed as silicon source gas at a flow rate of 50 sccm to 300 sccm, GeH₄ is fed as germanium source gas at a flow rate of 50 sccm to 300 sccm, HCl gas is fed at a flow rate of 30 sccm to 300 sccm, and H₂ gas is fed. During epitaxial growth of Si—Ge—C, SiH₃CH₃ as carbon source gas is also fed at a flow rate of about 2 sccm to 50 sccm. During deposition, boron source gas such as diborane is also fed so as to conduct doping of a p-type impurity, i.e., boron. The pressure inside the CVD deposition chamber is, for example, 100 Pa to 5000 Pa.

The Ge content in Si—Ge is preferably 5 at % to 40 at %. Addition of a small amount of C decreases the amount of strain but improves the thermal stability of the Si—Ge layer.

Epitaxial growth occurs over the surface of the silicon crystal and not over the surface of the insulator. After the epitaxial growth, the silicon oxide film 11 is removed.

SiH₄, Si₂H₆, Si₃H₈, or Si₃Cl₆ may be used as the silicon source gas instead of SiH₂Cl₂. Cl₂ may be used instead of HCl. GeH₂Cl₂ may be used instead of GeH₄.

Although the upper part of the polysilicon gate electrode of the pMOS transistor is also partially etched during the step of etching the source/drain region, Si—Ge grows over the polysilicon gate during the Si—Ge deposition step.

Referring now to FIG. 1G, a silicide layer, e.g., a NiSi layer 16, is formed over the surface of the silicon crystal and the epitaxial layer 13. For example, a nickel layer having a thickness of 10 nm to 20 nm is deposited by, for example, a sputtering method, and annealed at a temperature not more than 450° C. so as to allow nickel to react with silicon. The unreacted portion of the nickel layer is removed with a mixed solution of hydrogen peroxide and sulfuric acid, for example.

As shown in FIG. 1H, a silicon oxide film 21 is formed. For example, the silicon oxide film 21 with a thickness of 10 nm to 20 nm is formed by a plasma-enhanced CVD method that uses a parallel plate-type plasma-enhanced CVD apparatus and SiH₄ and N₂O as source gas at a substrate temperature less than 450° C. If the thickness of the silicon oxide film exceeds 20 nm, it becomes difficult to effectively apply stress to the substrate.

As shown in FIG. 11, an etching stopper film 22 having tensile stress is formed over the silicon oxide film 21. The etching stopper film 22 is, for example, a silicon nitride film. The silicon nitride film may be deposited by, for example, a plasma-enhanced CVD method that uses a parallel plate-type plasma-enhanced CVD apparatus and SiH₄, NH₃, and N₂ as source gas at a substrate temperature less than 450° C., and the film thickness may be 40 nm to 90 nm.

Referring to FIG. 1J, an interlayer insulating film 23, e.g., a silicon oxide film, is formed over the etching stopper film 22. As for the deposition conditions, the interlayer insulating film 23 having a thickness of 500 nm to 700 nm may be deposited by the plasma-enhanced CVD method that uses an inductively coupled plasma (ICP)-CVD apparatus and PH₃, SiH₄, and O₂ as source gas at a substrate temperature less than 450° C. The interlayer insulating film 23 is then planarized by CMP.

A resist pattern PR2 having openings is formed over the interlayer insulating film 23. The interlayer insulating film 23 is etched by using the resist pattern PR2 as an etching mask and the etching stopper film 22 as an etching stopper so as to form contact holes. As for the etching conditions, for example, a magnetron RIE apparatus is used with C₄F₆, Ar, and O₂ as etching gas.

After etching of the interlayer insulating film 23, the resist pattern PR2 may be removed by ashing. As an aftertreatment, fluorocarbon and the like adhering in the contact holes are removed by ammonium phosphate.

The etching stopper film 22 is etched by using the interlayer insulating film 23 with contact holes as a mask. Etching is conducted by using a magnetron RIE apparatus and mixed gas of CH₃F and O₂ as etching gas. The etching gas may further contain Ar and/or CF₄. The mixing ratio of CH₃F to O₂ is preferably CH₃F:O₂=1:1 to 1:2.

After etching the etching stopper film 22, the silicon oxide film 21 is etched to expose the NiSi layer 16. For example, etching is conducted using a magnetron RIE apparatus with mixed gas of C₄F₈, Ar, and O₂ as etching gas. The etching gas may further contain CF₄ and/or CHF₃. Preferably, the flow rate of Ar is 400 sccm to 800 sccm, the flow rate of C₄F₈ is 3 sccm to 10 sccm, and the flow rate of O₂ is 1 sccm to 5 sccm.

As shown in FIG. 1K, oxygen plasma 24 is generated in the same chamber as the etching chamber. As for the processing conditions of the oxygen plasma, a magnetron RIE apparatus is used and the chamber inner pressure is adjusted to 40 mTorr to 150 mTorr, RF power to 100 W to 500 W, the O₂ gas flow rate to 90 sccm to 300 sccm, the electrode temperature to −10° C. to 50° C., and the gap to 27 mm to 47 mm.

In the experimental examples described below, the chamber inner pressure was 90 mTorr, the RF power was 200 W, the O₂ flow rate was 180 sccm, the electrode temperature was 25° C., and the gap was 27 mm. The processing time was varied.

Preferably, the silicon substrate is kept in a vacuum or a reduced pressure atmosphere from the step of etching of the interlayer insulating film 23 to the step of the oxygen plasma treatment.

As shown in FIG. 1L, after the semiconductor substrate is discharged from the etching chamber, the semiconductor substrate is wet-processed with an ammonium phosphate solution 25 or the like to remove residue of fluorocarbon and the like. The semiconductor substrate may be subjected again to oxygen plasma treatment to remove the residue.

As shown in FIG. 1M, a TiN layer is sputter-deposited as a barrier metal layer in the contact holes. Then a W layer is formed in the contact holes by CVD using WF₆ and H₂ gas. The W layer over the interlayer insulating film 23 is removed by CMP to form conductive plugs 26.

Then an interlayer insulating film 27 composed of, for example, silicon oxide is deposited and wiring trenches are formed. A barrier layer composed of TaN or the like, and a Cu seed layer are formed by sputtering, and a Cu layer is deposited by plating. Subsequently, the Cu layer on the interlayer insulating film 27 is removed by CMP to form copper wiring 28. An interlayer insulating film 29 is formed and then copper wiring 30 is formed.

Sample A was prepared by forming the silicon oxide film 21 under the silicon nitride etching stopper film 22 and conducting oxygen plasma treatment after formation of contact holes. Sample B was made without a silicon oxide film 21 and without undergoing oxygen plasma treatment. The gate contact resistances for Samples A and B were measured.

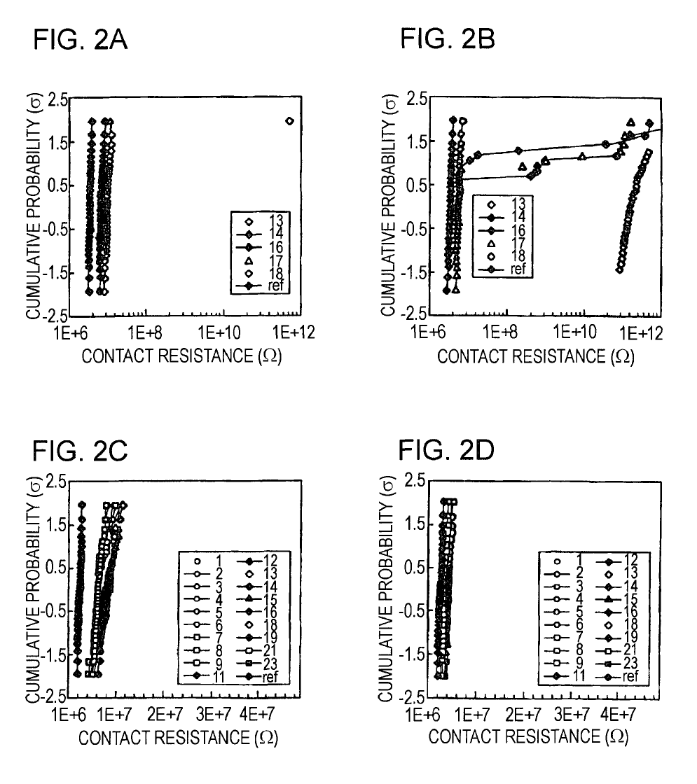

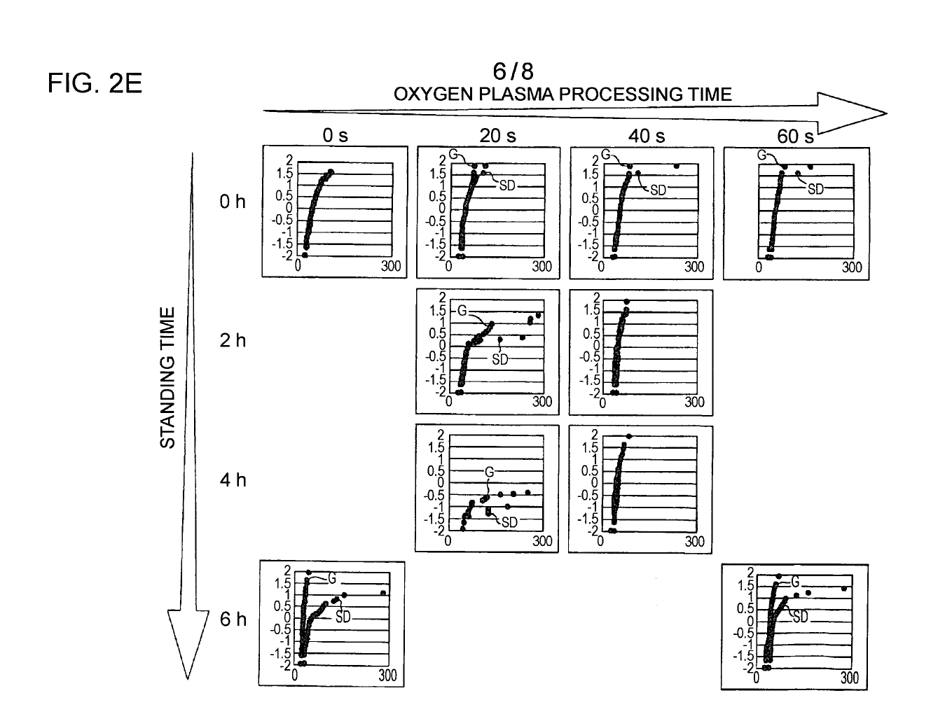

FIGS. 2A and 2B show the measurement results from Sample B. The horizontal axis indicates the gate contact resistance and the vertical axis indicates the cumulative probability of contact failure. Contact holes were formed in a plurality of wafers, and the wafers discharged from a low-pressure atmosphere were subjected to ashing treatment with oxygen plasma one by one. Then the conductive plugs 26 were formed and the gate contact resistance was measured. FIG. 2A shows the gate contact resistance of a pMOS transistor. The variation in observed gate contact resistances among the plurality of wafers was relatively small. FIG. 2B shows the gate contact resistance of an nMOS transistor. Observed contact values varied among the plurality of wafers. It should be noted here that the wafers that had to be left to stand longer after being discharged into air and before ashing tended to show larger contact resistances.

FIGS. 2C and 2D show the measurement results of Sample A. FIG. 2C shows the gate contact resistance of pMOS transistors. The variation in gate contact resistance among the wafers was small. FIG. 2D shows the gate contact resistance of nMOS transistors. Compared to FIG. 2B, the variation among the wafers was small.

FIG. 2E shows the gate contact resistances of samples that were subjected to oxygen plasma processing for 0 seconds, 20 seconds, 40 seconds, and 60 seconds and that were left to stand in air, after being discharged from the etching apparatus before being loaded to the ashing apparatus, for 0 hours, 2 hours, 4 hours, and 6 hours. In each of the graphs, the horizontal axis indicates the gate contact resistance value and the vertical axis indicates the probability of failure in terms of sigma. The graphs show the characteristics of the gate contact and the source/drain contact of nMOS transistors. G indicates the gate contact and SD indicates the source/drain contact.

At a standing time of 6 hours, the gate contact resistance and the source/drain contact resistance of nMOS transistors were both high irrespective of whether the length of time of oxygen plasma treatment was 0 seconds or 60 seconds. At a standing time of 0 hours and the length of time of oxygen plasma treatment of 0 seconds, the contact resistance increased slightly and decreased as the oxygen plasma processing time increased to 20 seconds and 40 seconds. In other words, the oxygen plasma treatment suppressed the increase in contact resistance. However, the contact resistance again increased at an oxygen plasma processing time of 60 seconds. At an oxygen plasma processing time of 20 seconds, the contact resistance increased as the standing time increased from 0 hours to 2 hours and to 4 hours. At an oxygen plasma treatment time of 60 seconds, the contact resistance increased despite a standing time of 0 hours. This is presumably because the NiSi surface is oxidized by oxygen plasma treatment.

The contact resistance is low irrespective of the standing time at an oxygen plasma processing time of 40 seconds. The preferred amount of the oxygen plasma treatment in terms of the amount of ashing of i-line resist was 305 nm to 463 nm.

In the embodiment described above, an oxide silicon film was laid under the etching stopper film and oxygen plasma treatment was conducted after formation of the contact holes.

Regarding to samples in 0 hours/0 seconds, 2 hours/40 seconds, and 4 hours/40 seconds, there was no difference between the gate contact and the source/drain contact.

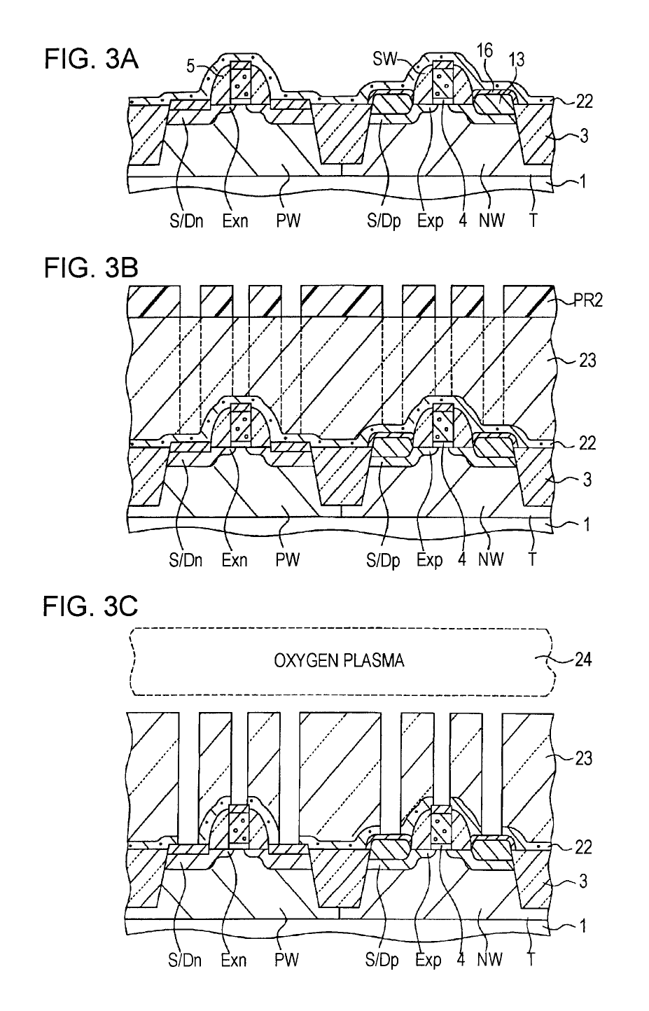

FIGS. 3A to 3C show another embodiment in which the step of forming the silicon oxide film is omitted from the steps of the embodiment shown in FIGS. 1A to 1M.

First, the steps shown in FIGS. 1A to 1G are conducted to form a NiSi layer 16 over a Si—Ge mixed crystal.

Then as shown in FIG. 3A, an etching stopper film 22 covering the NiSi layer 16 is formed. The etching stopper film 22 is, for example, a silicon nitride film.

As shown in FIG. 3B, an interlayer insulating film 23 is formed over the etching stopper film 22, and a photoresist pattern PR2 is formed over the interlayer insulating film 23. The interlayer insulating film 23 is etched by using the photoresist pattern PR2 as an etching mask and the etching stopper film 22 as an etching stopper. Then, the photoresist pattern PR2 may be removed by ashing. The etching stopper film 22 is then etched using the interlayer insulating film 23 with contact holes as a mask.

As shown in FIG. 3C, after etching of the etching stopper film 22, oxygen plasma 24 is generated in the same reaction chamber as the chamber in which the etching is performed.

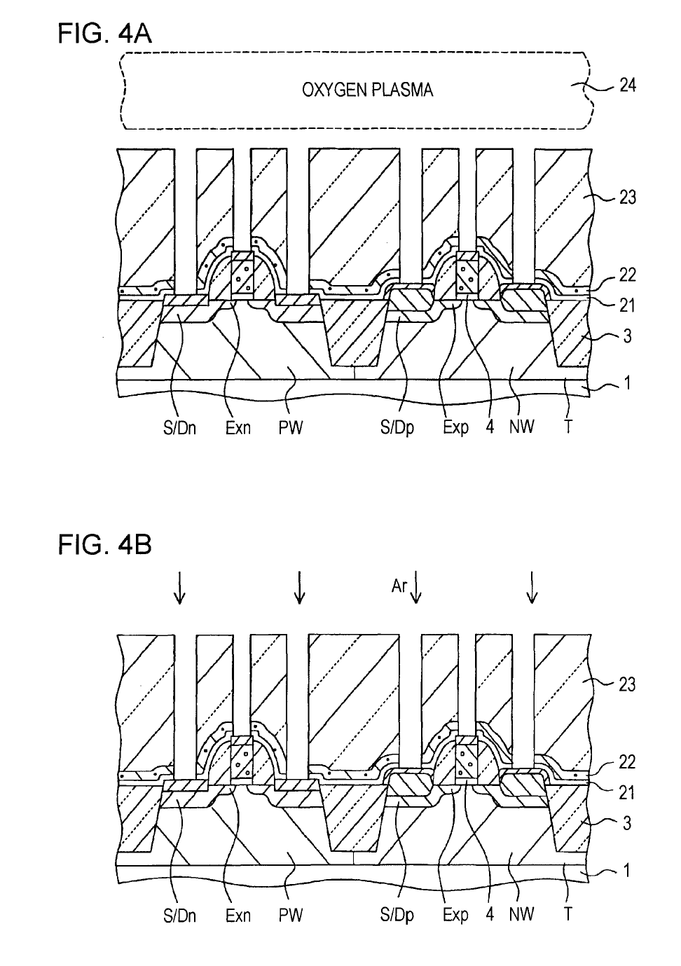

FIGS. 4A and 4B show a process according to another further embodiment. In this embodiment, the steps shown in FIGS. 1A to 1J are performed, but in the step shown in FIG. 1J, the silicon oxide film 21 is not removed and the NiSi layer 16 remains covered with the silicon oxide film 21.

Then, as shown in FIG. 4A, oxygen plasma 24 is generated inside the etching reaction chamber.

As shown in FIG. 4B, first, Ar plasma is generated inside the sputtering chamber, and the silicon oxide film 21 remaining in the contact holes is removed by RF sputtering treatment. The RF sputtering treatment is performed, for example, using an ICP apparatus, Ar gas flow rate is 20 sccm to 100 sccm, chamber inner pressure is 1 mTorr to 3 mTorr, RF power of the upper electrode is 750 W, RF power of the lower electrode is 200 W to 250 W; and processing time is 3 seconds to 20 seconds.

Then, the step of forming the conductive plugs and the upper wirings is conducted as shown in FIG. 1M.

Although the present invention has been described by way of embodiments above, the present invention is not limited to these embodiments. Various other modifications, substitutions, improvements, and combinations are possible.

What is claimed is:

1. A method of manufacturing a semiconductor device comprising:
forming a first active region in a semiconductor substrate;
forming a first gate electrode, a first source, and a first drain in the first active region;
forming a mixed crystal layer including silicon and germanium over the first source and the first drain;
forming a silicide layer over the mixed crystal layer;
forming a silicon oxide film over the silicide layer;
forming a first insulating film over the silicon oxide film;
forming a second insulating film over the first insulating film;
forming a contact hole by etching the second insulating film, the first insulating film, and the silicon oxide film;
performing a first oxygen plasma treatment after forming the contact hole; and
forming a conductive plug in the contact hole.

2. The method according to claim 1, wherein the first insulating film includes a silicon nitride film.

3. The method according to claim 2, wherein the silicon nitride film has tensile stress.

4. The method according to claim 3, wherein
forming the contact hole by etching is conducted in a first reaction chamber and the first oxygen plasma treatment is conducted in the first reaction chamber without having the semiconductor substrate exposed to air.

5. A method of manufacturing a semiconductor device comprising:
forming a first active region in a semiconductor substrate;
forming a first gate electrode, a first source, and a first drain in the first active region;
forming a mixed crystal layer including silicon and germanium over the first source and the first drain;
forming a silicide layer over the mixed crystal layer;
forming a first insulating film over the silicide layer;
forming a second insulating film over the first insulating film;
forming a contact hole by etching the second insulating film and the first insulating film and then performing a first oxygen plasma treatment in a first reaction chamber under a reduced pressure; and
forming a conductive plug in the contact hole.

6. The method according to claim 5, further comprising forming a silicon oxide film over the mixed crystal layer before forming the first insulating film.

7. The method according to claim 6, wherein in forming the contact hole, the silicon oxide film is etched to expose the silicide layer.

8. The method according to claim 5, wherein the silicide layer includes a nickel silicide layer.

9. The method according to claim 5, wherein, after the first oxygen plasma treatment, the semiconductor substrate is discharged from the first reaction chamber and a second oxygen plasma treatment is performed.

10. The method according to claim 5, wherein the first active region is n-type active region.

11. The method according to claim 10, further comprising:
forming a second active region of p-type in the semiconductor substrate; and
forming a second gate electrode, a second source, and a second drain in the second active region.

12. The method according to claim 11, wherein the first insulating includes a silicon nitride film, and the silicon nitride film is formed to cover the second gate electrode, the second source, and the second drain.

13. The method according to claim 12, wherein the contact hole is formed by etching the second insulating film using a resist layer over the second insulating film as a mask, and etching the silicon nitride film and the silicon oxide film using the interlayer insulating film as a mask.

14. The method according to claim 5, further comprising:
forming grooves in the first source and the first drain by etching the first source and the first drain after formation of the first active region and before forming the mixed crystal layer.

15. The method according to claim 6, wherein the silicon oxide film has a thickness of 10 nm to 20 nm.

16. A semiconductor device comprising:
a semiconductor substrate;
a first active region in the semiconductor substrate;
a first gate electrode in the first active region;
a mixed crystal layer including silicon and germanium at both sides of the first gate electrode;
a silicide layer over the mixed crystal layer;
a silicon oxide layer over the silicide layer;
a first insulating layer over the silicon oxide layer;
a second insulating film over the first insulating layer;
a contact hole penetrating the second insulating film, the first insulating layer, and the silicon oxide layer, the contact hole reaching the silicide layer; and
a plug in the contact hole.

17. The semiconductor device according to claim 16, wherein the silicide layer includes a nickel silicide layer.

18. The semiconductor device according to claim 16, wherein the first insulating layer includes a silicon nitride layer.

19. The semiconductor device according to claim 16, wherein the thickness of the silicon oxide layer is 10 nm to nm.

20. The semiconductor device according to claim 18, wherein the silicon nitride film has tensile stress.
